(19) United States
(12) Patent Application Publication
(10) Pub. No.: US 2012/0012155 A1
(43) Pub. Date: Jan. 19, 2012

(54) SOLAR RECEIVER WITH FRONT AND REAR HEAT SINKS

(75) Inventors: Brian J. Ignaut, San Mateo, CA (US); Robert L. MacDonald, Sunnyvale, CA (US)

(73) Assignee: SKYLINE SOLAR, INC., Mountain View, CA (US)

(21) Appl. No.: 13/244,073

(22) Filed: Sep. 23, 2011

Related U.S. Application Data
(60) Provisional application No. 61/386,852, filed on Sep. 27, 2010.
(60) Provisional application No. 61/512,530, filed on Jul. 28, 2011.

(51) Int. Cl. H01L 31/052; H01L 31/18; H01L 31/024

(52) U.S. Cl. 136/246; 136/259; 438/64; 257/E31.131

(57) ABSTRACT

In one aspect of the present invention, a solar receiver with an improved heat sink design will be described. The solar receiver includes a photovoltaic cell and a heat spreader plate having a frontside and an opposing backside. The photovoltaic cell is positioned on the frontside of the heat spreader plate. Multiple front and rear heat sink fins are attached to and extend out of the frontside and the backside of the heat spreader plate, respectively. In various implementations, the front heat sink fins are positioned adjacent to, above and below the photovoltaic cell.

### CROSS-REFERENCE TO RELATED APPLICATION(S)

This patent application claims priority to U.S. Patent Application No. 61/386,852, entitled “Solar Receiver with Wrap Around Heat Sink,” filed Sep. 27, 2010, and U.S. Patent Application No. 61/512,530, entitled “Photovoltaic Panel,” filed Jul. 28, 2011, which are incorporated herein in their entirety for all purposes.

### FIELD OF THE INVENTION

The present invention relates to solar collection systems. More specifically, the present invention relates to a solar receiver for use in a concentrating solar collector.

### BACKGROUND OF THE INVENTION

Photovoltaic concentrating systems use minors or reflectors to focus sunlight onto one or more solar receivers to generate electricity. The focusing of sunlight on the solar receiver generates large amounts of heat. Since excessive heat buildup can damage the solar receiver and reduce the efficiency of the photovoltaic cells in the solar receiver, a cooling mechanism, such as a heat sink, is typically used to transfer the heat away from the cells.

There are a wide variety of solar receiver and heat sinks designs. By way of example, one such design is described in U.S. patent application Ser. No. 12/622,764 (hereinafter referred to as the '764 application.) FIGS. 6-8 of the '764 application relate to a solar receiver that includes a photovoltaic cell, heat sink fins and a holder made of a thermally conductive material. The holder, which resembles a trough, includes a base that forms the bottom of the trough and integrally formed inclined plates that form the sides of the trough. The heat fins, which are arranged in a row, have a trapezoidal cut-out section that is attached to the underside of the holder. Heat generated at the photovoltaic cell flows through the base, the inclined plates and from there is conveyed to the fins, where it can dissipated into the ambient environment.

While existing solar receivers and heat sinks work well, there are continuing efforts to develop more efficient and cost-effective designs to meet the needs of a variety of solar applications.

### SUMMARY OF THE INVENTION

In one aspect of the present invention, a solar receiver with an improved heat sink design will be described. The solar receiver includes a photovoltaic cell and a heat spreader plate having a frontside and an opposing backside. The photovoltaic cell is positioned on the frontside of the heat spreader plate. Multiple front and rear heat sink fins are attached to and extend out of the frontside and the backside of the heat spreader plate, respectively. In various implementations, the front heat sink fins are positioned adjacent to, above and below the photovoltaic cell.

In some embodiments, the front heat sink fins are arranged in the same vertical orientation as the rear fins. In other embodiments, the front heat sink fins are instead arranged horizontally and are arranged to fan out around the photovoltaic cell. This arrangement helps ensure air flow across the major surfaces of either the rear heat sink fins or the front heat sink fins, irrespective of which direction the wind is blowing.

The front and rear heat sink fins may be arranged in various configurations. Some designs involve front and rear heat sinks that are entirely separate from one another. In other designs, the front and rear heat sink fins are contiguous and/or connected to one another. Various rear heat sink fin designs have a beveled back corner, which allows the backsides of two adjacent solar receivers to be positioned closer together. This approach works well with collector designs that, for example, position adjacent solar receivers in the center of the collector, where the faces of the cells on the adjacent receivers are facing away from one another.

Various implementations involve arranging the heat sink fins in a longitudinally extended row. There are gaps between adjacent fins in the row that define vertical air flow channels. The channels allow free convective air flow to cool the fins and reduce heat buildup in the solar receiver.

The solar receiver may also include secondary optics. The secondary optics can be positioned on the front heat sink fins adjacent to the photovoltaic cell. In various embodiments, the secondary optics are minors or reflectors that direct light into the cell using a second reflection. Each secondary optic can be physically supported by a single front fin or multiple front fins, depending on the fin arrangement on the solar receiver.

In another embodiment of the present invention, each heat sink fin includes a foot section and a fin section. The foot section may, for example, be a bent portion at the end of the fin. Each foot section includes a base portion and a offset grounding tab. The base portion and the offset grounding tab define a space adjacent the base portion that is configured to receive the grounding tab of another fin. The foot sections of two adjacent fins can be welded together at that location to provide for electrical continuity between adjacent fins. The foot sections cooperate to form a substantially continuous attachment surface. The attachment surface formed from the foot sections can be used to attach the fins to one or more components, such as the heat spreader plate and/or a secondary optic.

### BRIEF DESCRIPTION OF THE DRAWINGS

The invention and the advantages thereof, may best be understood by reference to the following description taken in conjunction with the accompanying drawings in which:

FIGS. 1A-1B are diagrammatic perspective and cross-sectional views of a collector according to a particular embodiment of the present invention.

FIGS. 2-3 are diagrammatic cross-sectional and perspective views of a solar receiver according to a particular embodiment of the present invention.

FIGS. 4A-4B are diagrammatic cross-sectional and perspective views of a solar receiver according to another embodiment of the present invention.

FIG. 5 is a diagrammatic cross-sectional view of a solar receiver with secondary optics according to a particular embodiment of the present invention.

FIG. 6A is a diagrammatic perspective view of a heat sink fin according to a particular embodiment of the present invention.

FIG. 6B is an enlarged view of a foot section of the heat sink fin illustrated in FIG. 6A.

FIG. 6C is a diagrammatic perspective view of multiple attached fins according to a particular embodiment of the present invention.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present invention relates generally to concentrating solar collection systems. More specifically, the present invention relates to a solar receiver with an improved heat sink design. Various embodiments of the present invention involve a solar receiver with a photovoltaic cell mounted on a heat spreader plate. Front and rear heat sink fins extend out of both sides of the heat spreader plate. The use of both front and rear heat sink fins facilitates the dissipation of heat from the solar receiver.

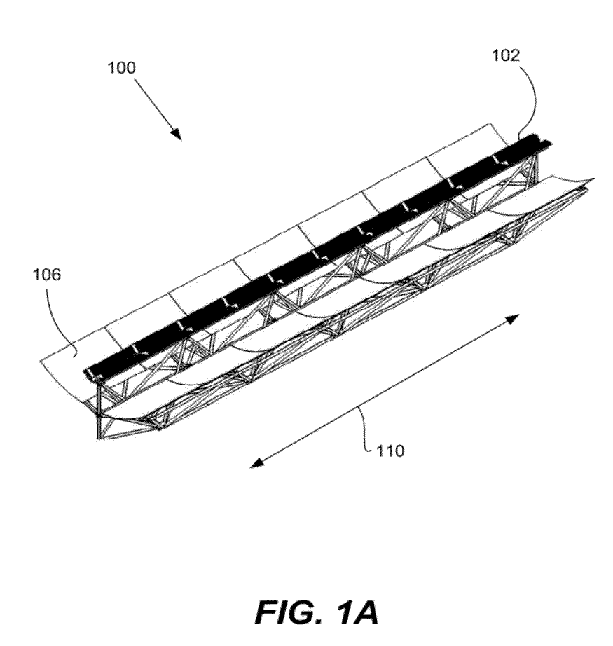

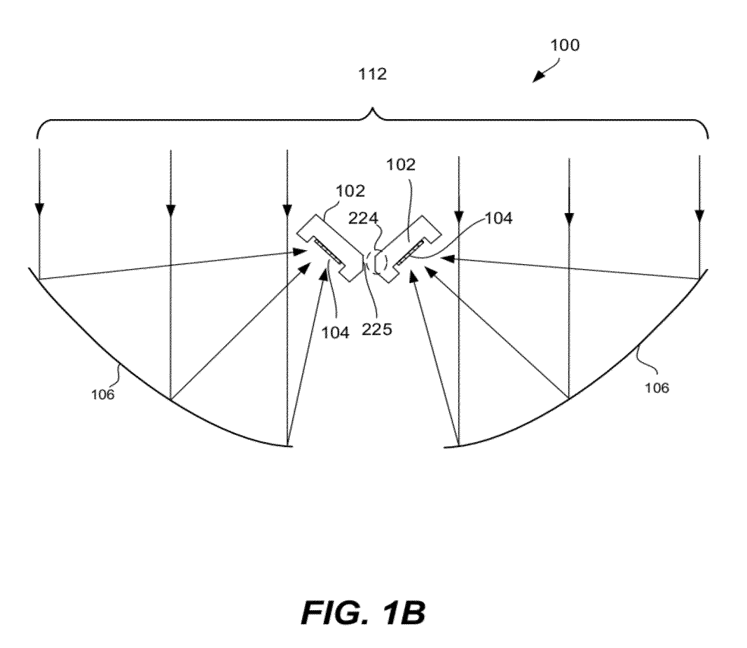

Referring initially to FIGS. 1A and 1B, a solar collector 100 with an improved solar receiver (or equivalently receiver, solar panel, or panel) 102 according to a particular embodiment of the present invention will be described. The solar receiver may be used in any suitable collector, including any collector described in U.S. patent application Ser. No. 12/982,701, which was filed by the assignee of the present application and is incorporated by reference herein in its entirety for all purposes. In the illustrated embodiment, for example, the solar collector 100 includes reflector panels 106 that extend in a longitudinal direction 110 and that are arranged in the shape of a “U.” The reflector panels 106 are arranged to reflect incident sunlight inward towards solar receivers 102 positioned at the center of the collector 100. The collector 100 is arranged to track the movement of the sun in at least one dimension.

In various implementations, each solar receiver 102 includes a string of photovoltaic cells 104 that are arranged side by side to extend in the longitudinal direction 110. The reflector panel 106 directs incident sunlight 112 to form a flux line on the cell string. (Various reflector arrangements and techniques for forming the flux line are described in U.S. patent application Ser. No. 12/728,149, which was filed by the assignee of the present application and is incorporated by reference herein for all purposes.) The photovoltaic cells 104 absorb the sunlight and generate electrical current as well as substantial amounts of heat. Since the efficiency of photovoltaic cells 104 declines as their temperature increases, it is highly desirable to use a heat sink or another cooling mechanism to reduce heat buildup.

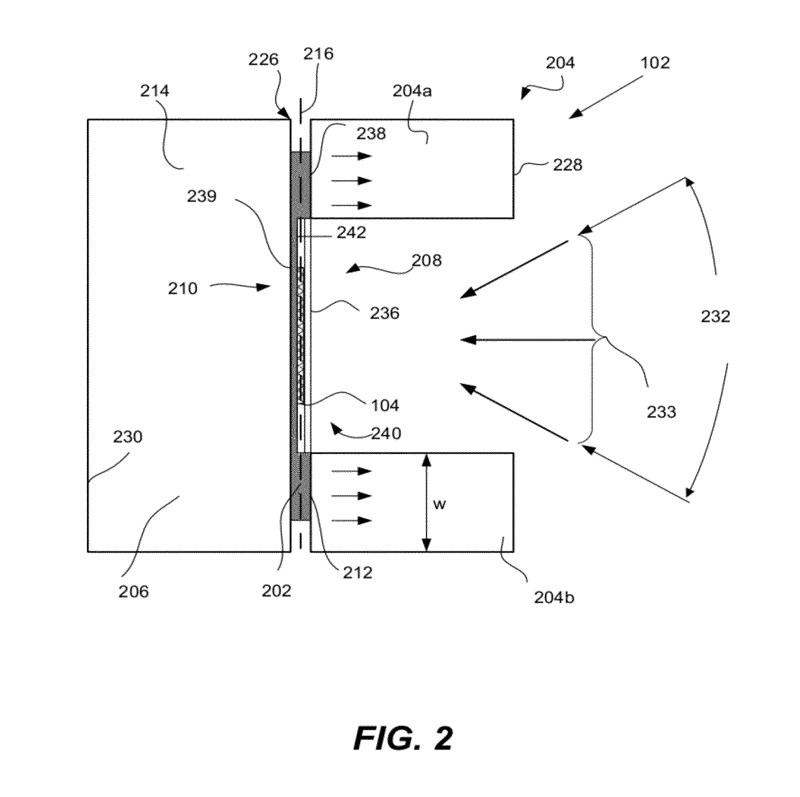

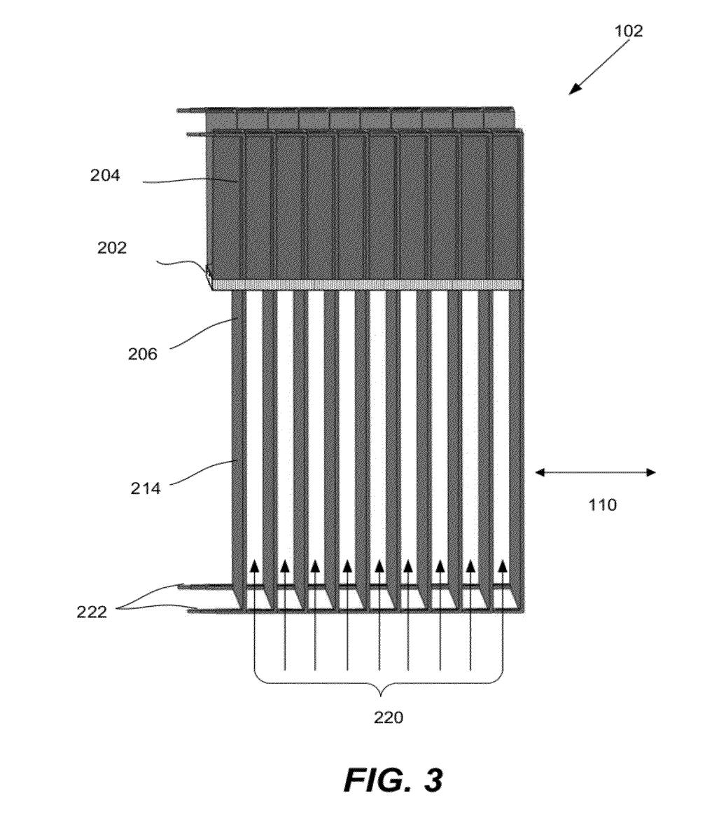

Referring now to FIGS. 2 and 3, a solar receiver 102 with an improved heat sink design according to a particular embodiment of the present invention will be described. FIGS. 2 and 3 are diagrammatic cross-sectional and perspective views of a solar receiver 102 that includes a photovoltaic cell 104, a heat spreader plate 202 and multiple front and rear heat sink fins 204/206. The photovoltaic cell 104 is mounted on a frontside 208 of the heat spreader plate 202. The front fins 204 include upper and lower front fins 204a/204b that are positioned above and below the cell 104. They are attached to and extend out of the frontside 208 of the heat spreader plate 202. The rear heat sink fins 206 are attached to and extend out of the opposing backside 210 of the heat spreader plate 202. The reflector panels 106 of FIG. 1B of the collector 100 direct concentrated light 233 to the photovoltaic cell 104.

Heat is generated at the photovoltaic cell 104 and is conveyed through the heat spreader plate 202 to the fins. Heat sink fins are attached to both sides of the heat spreader plate 202 and are in close proximity to the cell 104. Accordingly, the heat from the photovoltaic cell 104 does not have to travel far to reach the fins. Each fin interfaces with the heat spreader plate 202 along a relatively large contact area. In the illustrated embodiment, for example, each fin contacts the heat spreader plate 202 along a connecting edge 212 that extends mostly or entirely across the width W of the fin. As indicated by the arrows in FIG. 3, this arrangement allows heat to be transferred widely through the fin and more quickly into the ambient environment. As will be discussed later in the application, various fin designs include a foot section that can be attached to the heat spreader plate, which further increases the amount of thermal contact between the heat spreader plate 202 and the fin.

The fins are made of a thermally conductive material, such as aluminum or another suitable metal. They may be attached to the heat spreader plate 202 in various ways, including welding, brazing, solder, swaging, the use of adhesives or fasteners, etc. Generally, multiple fins of each type (rear fin 206, upper front fin 204a, lower front fin 204b) are arranged in a row and spaced apart from one another along the longitudinal direction 110 (which is into the page in FIG. 2.) Each fin has a large major surface 214 for dissipating heat from the solar receiver. In the illustrated embodiment, the major surface 214 of each fin is substantially perpendicular to a plane defined by the photovoltaic cell 104 (referred to herein as the cell plane 216) and parallel to the major surfaces of the other front fins 204 and/or rear fins 206, although this is not a requirement and other arrangements are also possible, as will be described later in this application.

The spacing apart of the fins creates air channels between the fins that help cool the solar receiver 102. FIG. 3 is a diagrammatic perspective view of the solar receiver 102 and the air channels 220 according to a particular embodiment of the present invention. The air channels 220 allow for free convective air flow over the major surfaces of the fins, which helps transfer heat out of the solar receiver 102. In the illustrated embodiment, the air channels 220 extend in a vertical direction that is perpendicular to the longitudinal direction 110. Some designs involve air channels in which the free flow of air in the vertical direction through the channel is impeded only by the heat spreader plate 202.

In various embodiments, stabilizers 222 are attached to the ends of the fins to help maintain the spacing between the fins. In the illustrated embodiment, for example, each rear fin 206 has a first end, which is attached to the heat spreader plate 202, and a second end that is attached to a stabilizer 222. Each stabilizer 222 is a thin, linear rod or beam that extends in the longitudinal direction 110 and that connects to the second ends of multiple rear fins 206 to help hold them in place. Since the stabilizer 222 is quite thin and extends along a line defined by the edges of the attached fins, it leaves ample room for air to flow vertically through the air channels 220.

Although the fins in the illustrated embodiment appear to be generally rectangular, in other embodiments they may have different dimensions and shapes. By way of example, in some implementations a corner of a rear fin 206 is beveled. That is, instead of a corner of the fin being composed of two edges that meet at a right angle, the corner instead involves at least three edges, in which two perpendicularly aligned edges are linked by a third edge.

An example of a rear fin with a beveled corner 224 is shown in FIG. 1B, which illustrates two solar receivers 102. The two solar receivers 102 are positioned adjacent to one another with the faces of their respective photovoltaic cells 104 facing outward and away from one another. The solar receivers 102 are generally symmetrically arranged and tilted downward. That is, the faces of the photovoltaic cells 104 are not parallel to one another, but are instead pointed towards the reflector panels 106, which are positioned lower than the cells in the collector 100. If the beveled corner 224 did not exist and the major surfaces of the fins were entirely rectangular, the sharp corners of the fins would force the receivers to be placed further apart. The beveled corner 224 involves eliminating the sharp, right angle corner formed by two converging edges of the fin and replacing it with a third edge 225. In various embodiments, the third edges 225 of the centrally located solar receivers 102 are generally parallel to one another. Accordingly, the solar receivers 102 can be positioned closer together.

The design of each fin can vary between different implementations. As will be discussed later in this application, some fins may have folded regions, cut-out regions and other features that facilitate the connecting of the fins to one another and to other components of the solar receiver. In some implementations, at least some of the fins (e.g., the rear fins 206, the front fins 204, the upper front fins 204a and/or the lower front fins 204b) may be integrally formed together with a base plate or the heat spreader plate 202 to form a comb-like structure. Fins of a particular type in the solar receiver (e.g., rear fins, front fins) may have identical or different shapes and designs.

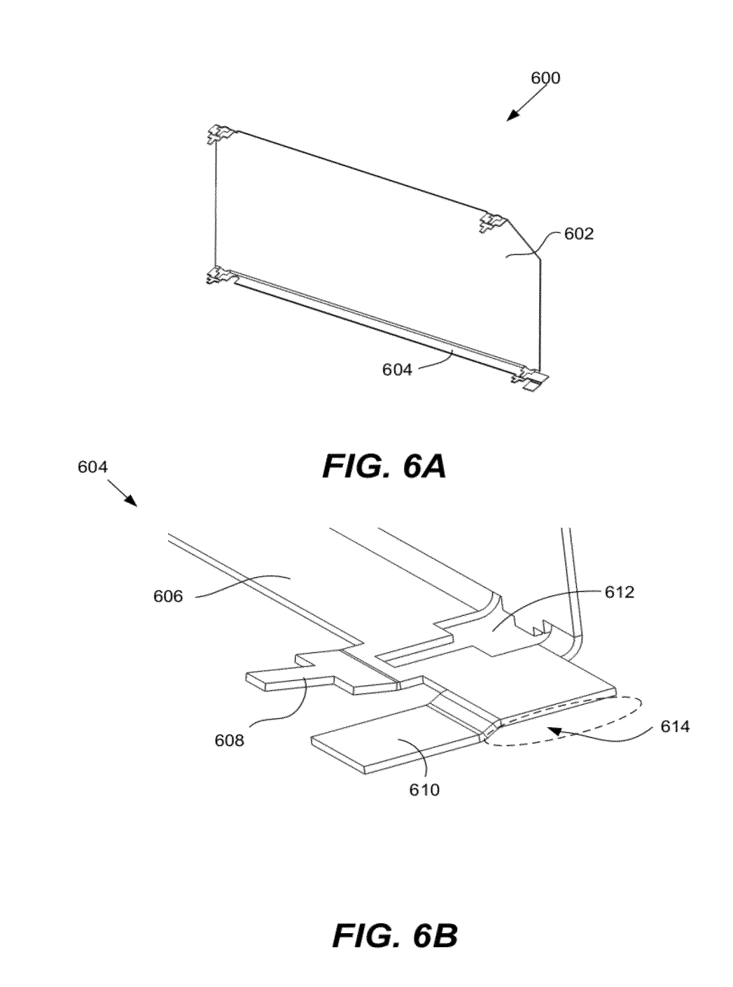

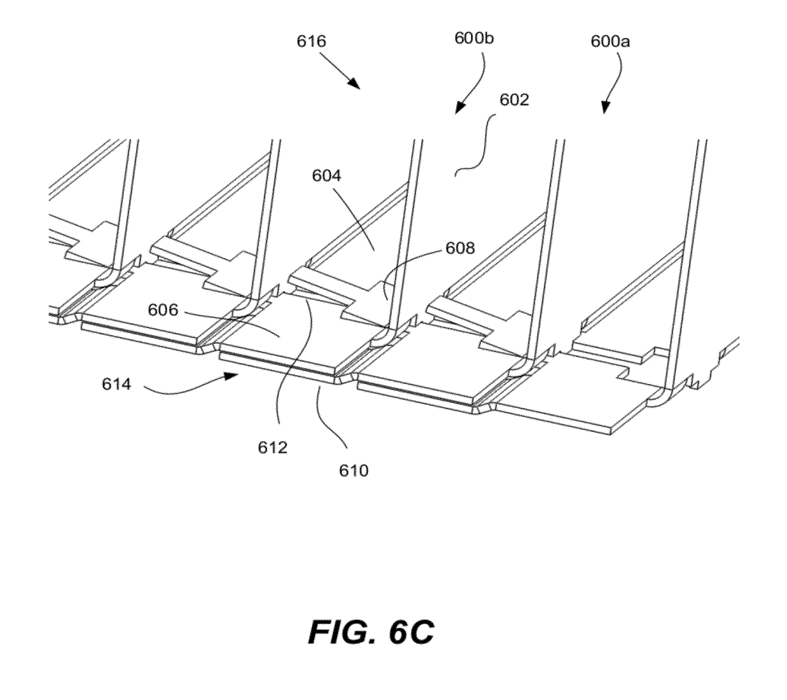

The front and rear fins 204/206 may or may not be aligned and/or connected to one another. More specifically, each front fin 204 may be entirely separate and/or mechanically independent from all of the rear fins 206. Configuring the fins in this manner allows the fins to be pressed firmly against the heat spreader plate during the assembly process. Also having mechanically independent front and rear fins reduces the required mechanical tolerances on the fins, since the attachment of the fins to the heat spreader plate involves only the mating of two nominally flat surfaces, the rear surface of the heat spreader plate 239 and the foot of the fin (for example 604 in FIG. 6). This helps to facilitate a low thermal resistance joint between the fins and heat spreader plate. Alternatively, each front fin 204 may be contiguous with and/or connected to an associated rear fin 206. By way of example, FIG. 2 refers to a region 226 where the front and rear fins 204/206 are optionally connected and/or continuous with one another. In some embodiments, each front fin 204 is aligned with and positioned opposite from one of the rear fins 206. In other embodiments, the front and rear fins 204/206 are not aligned i.e., each front fin 204 is offset along the longitudinal direction 110 from all of the rear fins 206.

The use of front fins 204, which is uncommon among prior art solar receiver designs, can greatly expand the total heat sink surface area. In some embodiments, the front fins account for between 5% and 50% of the total surface area of all fins on the solar receiver. In still other embodiments, the front edge 228 of the front fin and the back edge 230 of the rear fin are approximately the same distance from the heat spreader plate 202.

Despite the position of the front heat sink fins 204, the fins generally do not block incoming concentrated light. In various embodiments, the reflector panels 106 of the collector 100 of FIG. 1B are arranged to direct concentrated light 233 between the upper and lower front fins 204a/204b so that the light reaches the photovoltaic cell 104 unimpeded. To achieve this, various collector designs involve reflector panels 106 that are arranged to direct light at a relatively small incidence cone angle 232 relative to a plane perpendicular to the longitudinal direction 110. In various collector designs, the cone angles may be approximately between 30 and 120 degrees, although smaller and greater cone angles are also possible.

The heat spreader plate 202 may be made of any suitable thermally conductive material, such as aluminum. Although the heat spreader plate 202 in FIG. 2 is depicted as plate- or sheet-like, it may have other shapes or be connected to a larger structure. An advantage of a flatter, plate-like shape is that it may be easier and more cost-effective to manufacture. In some embodiments, the heat spreader plate 202 is thin and flat enough such that it can be laminated together with the photovoltaic cell and a protective cover to form a receiver subassembly, as described in U.S. Pat. No. 7,709,730, which is owned by the assignee of the present application and is hereby incorporated by reference in its entirety for all purposes. The heat spreader plate 202 may be fabricated using any known technique, such as an extrusion process.

The frontside and backside of the heat spreader plate may each include a single, flat surface or include multiple flat surfaces and/or recesses. In the illustrated embodiment, for example, the frontside of the heat spreader plate 202 includes a front surface 238 that extends above and below the photovoltaic cell. The front fins 204 are attached to and extend substantially perpendicular out of the front surface 238. There is also a recessed surface 242 that is downset from the front surface 238 and that is at the bottom of a recess 240 in the front surface 238. The photovoltaic cell 104 is positioned in the recess 240. The recess 240 helps hold the cell in position within the heat spreader plate. In some embodiments, a protective cover 236, which may be generally coplanar with the front surface 238 of the heat spreader plate 202, is applied over the cell 104 and/or is also positioned within the recess 240. The backside of the heat spreader plate includes a flat back surface 239, which is opposed to the front surface 238. The rear fins 206 are attached to and extend perpendicular out of the back surface 239.

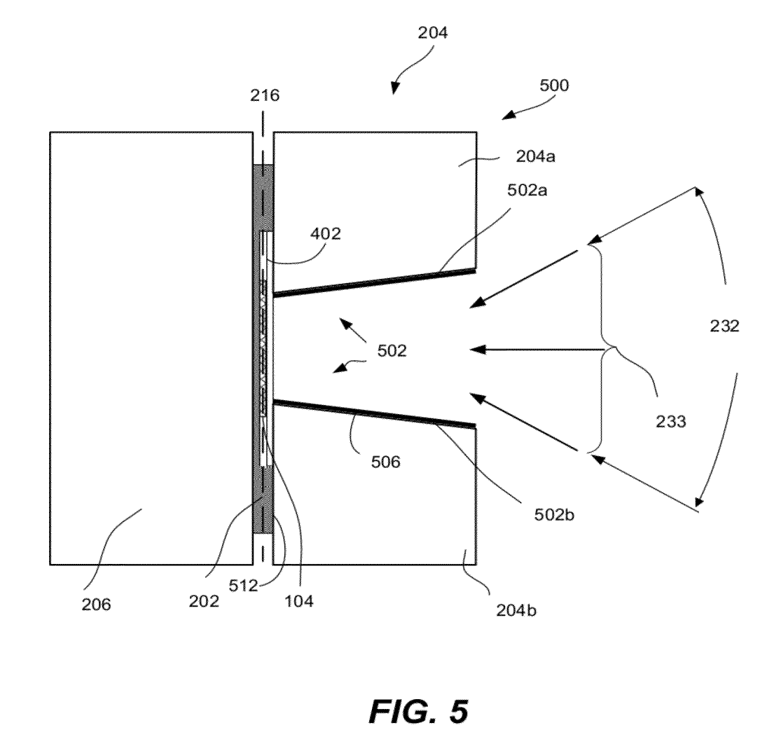

The photovoltaic cell 104 may be of any suitable type known to persons of ordinary skill in the art. Various cell designs are described in U.S. patent applications Ser. Nos. 12/784,360, and 61/495,663 which were filed by the assignee of the present application and are incorporated herein by references in its entirety for all purposes. In some implementations, a protective, transparent cover 236 overlies the face of the photovoltaic cell 104. An encapsulant (not shown) may be applied around the cell to electrically isolate the cell and protect it cell from damage. Some implementations involve a photovoltaic cell 104 that includes bus bars at its edge regions, which are overlapped by the front fins. (An example of this arrangement is shown in solar receiver illustrated in FIG. 5, which includes a photovoltaic cell 104 with edge regions 402 and overlapping front fins 204.) Since the bus bars prevent sunlight from reaching the underlying semiconductor material, it does not substantially affect the efficiency of the cell 104 to have the fins cover and shade the edge regions of the cell.

The aforementioned features distinguish the solar receiver from various prior designs. By way of example, the prior art solar receiver discussed in the Background section has a heat spreader (i.e., a holder) that is shaped like a trough, instead of a plate or sheet. Accordingly, the trough heat spreader is not as easily manufactured, nor can it be easily laminated together with the photovoltaic cell. Additionally, the prior art solar receiver does not involve front and rear fins that are attached to both sides of a heat spreader. Instead, the fins of the prior art solar receiver attach only to the underside of the holder. This arrangement transfers heat from the cell to the fins in a less efficient manner.

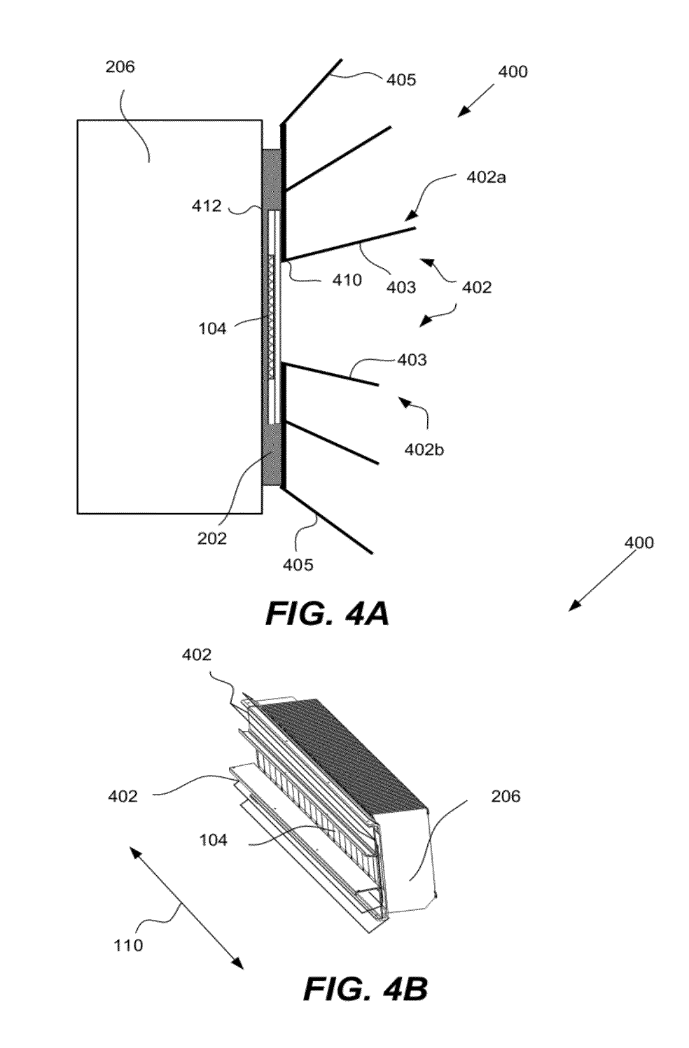

Referring next to FIGS. 4A and 4B, a solar receiver 400 with a different arrangement of front and rear fins 402/206 according to a particular embodiment of the present invention will be described. The solar receiver is generally similar to the solar receiver illustrated in FIG. 2, except that the front fins 402 are oriented in a different manner. That is, the upper and lower front fins 402a/402b fan out at different angles from the frontside of the heat spreader plate 202. Additionally, while the major surfaces of rear fins 206 are arranged vertically, perpendicular to the longitudinal direction, the front fins 402 are arranged horizontally, parallel to the longitudinal direction.

The different orientation of the front fins 402 can help facilitate air flow over the major surfaces of the front fins 402. Since the front fins 402 are horizontally oriented and fan out in different directions, air can be channeled between at least some of the fins even when the wind is coming from above, below or from the sides of the solar receiver. That is, the air flow is less likely to be blocked by the major surface of a front fin 402. As air flows through the channels between the fins, it can help transfer heat away from the solar receiver to the ambient environment.

The front and rear fins 402/206 may be arranged in a wide variety of ways, depending on the needs of a particular application. In some embodiments, the normal to the major surface of one or more of the front and/or rear fins is substantially perpendicular to the longitudinal direction 110. Each of the front and/or rear fins may be planar, non-planar and/or separate from one another. At least some of the front and/or rear fins may be formed integrally with one another, a base plate and/or the heat spreader plate 202 to form a comb-like heat sink structure. In the illustrated embodiment, each front heat sink 402 connects to the heat spreader plate 202 along a connecting edge 410 that extends parallel to the longitudinal direction 110. The rear fins 206 connect to the head spreader plate 202 along a connecting edge 412 that extends perpendicular to the longitudinal direction 110. It should be appreciated that a wide variety of fin arrangements are possible beyond what is shown in the drawings.

Different fins on the frontside of the heat spreader plate may serve different functions. In some embodiments, the major surfaces of the innermost fins 403 (i.e., the fins closest to the photovoltaic cell 104) are each attached to and physically support a secondary optic or minor that is adjacent to the photovoltaic cell 104. As discussed below in connection with FIG. 5, the secondary optic may be a longitudinally extended mirror or reflector that is arranged to direct light into the cell using a second reflection. The outermost fins 405 may serve as a scoop to help deflect air through the rear heat sink.

Referring next to FIG. 5, a solar receiver 500 with secondary optics 502 according to a particular embodiment of the present invention will be described. The solar receiver 500, which may include any of the features discussed in connection with FIGS. 1-4, includes an upper secondary optic 502a and a lower secondary optic 502b, which are positioned adjacent to opposing edges of the photovoltaic cell 104. The upper and lower front fins 204a/204b physically support and are attached to the upper and lower secondary optics 502a/502b, respectively.

The secondary optics 502 are arranged to direct light that was already reflected by the reflector panels 106 of the collector 100 (e.g., as seen in FIG. 1B) into the photovoltaic cell 104. The secondary optics 502 can help increase the amount of light that is captured by the solar receiver, help compensate for alignment problems with the reflector panels and help form a more uniform flux line on the photovoltaic cell. In the illustrated embodiment, the secondary optics 502 appear to be of the same size, but in some applications they may have different sizes and orientations. The secondary optics may be curved or flat and formed from any suitably reflective material, such as aluminum.

Edges 506 of the front fins 204 are attached to and help hold each secondary optic 502 in position. Thus, an additional, separate structure is not required to support the secondary optic 502. In the illustrated embodiment, the secondary optic is a reflector or mirror that extends in the longitudinal direction, which is supported by a row of front fins 204 that are also arranged side by side in the longitudinal direction. In some designs, this causes the major surfaces of the front fins 502 to extend perpendicular out of a back surface of the secondary optic. Each front fin 204 is thus attached to two different structures along two different adjacent edges. One edge 512 is attached to the heat spreader plate 202, while the other edge 506 connects to the secondary optic.

Referring next to FIGS. 6A-6B, a heat sink fin 600 according to a particular embodiment of the present invention will be described. FIG. 6A is a diagrammatic perspective view of a heat sink fin 600 that includes a fin section 602 and a foot section 604. FIG. 6B is an enlarged view of the foot section 604 illustrated in FIG. 6A. The heat sink fin 600 may be any fin described in this application e.g., an upper front fin, a lower front fin or a rear fin. The foot section 604, which may be formed by a fold at an end of the fin 600, is used to attach adjacent fins together as well as physically support another component in the solar receiver, such as a heat spreader plate or a secondary optic.

The foot section 604 has various features that allow it to be connected to the foot sections of other fins. In the illustrated embodiment of FIG. 6B, for example, the foot section 604 includes a base portion 606, an interlocking tab 608 and a grounding tab 610. The base portion 606 extends along the length of one edge of the fin section 602 and extends generally perpendicular to the fin section. The interlocking tab 608 extends out from the base portion 606. There is a cut-out section 612 in the base portion 606 that generally matches the profile of the interlocking tab 608. The grounding tab 610 also extends out from the base portion 610 and is offset from a surface of the base portion 606. The offset grounding tab 610 and the base portion 606 help define a grounding tab space 614 adjacent the base portion 606 and adjacent to the grounding tab 608 that is arranged to receive the grounding tab of an adjacent fin.

Referring next to FIG. 6C, the connecting of the foot sections 604 of adjacent fins 616 according to a particular embodiment of the present invention will be described. The adjacent fins are arranged such that the major surfaces of their fins sections 602 are generally parallel to one another and their foot sections 604 are arranged generally coplanar with one another. This arrangement facilitates mating the foot sections 604 against the flat rear surface of the heat spreader plate (239 in FIG. 2) enabling formation of a low thermal resistance connection. The interlocking tab 608 of the foot section 604 of the first fin 600a is inserted into and engages the matching cut-out section 612 in the adjacent second fin 600b. To further secure the fins together, the grounding tab 610 of the first fin 600a is positioned in the grounding tab space 614 under the base portion of the second fin 608. The grounding tab 608 of the first fin 600a can then be spot welded, or connected in some other manner such as soldering or crimping to the base portion 606 of the second fin 600b. The connection between first fin 600a and second fin 600b ensures electrical continuity between the fins. By repeating this type of connection for all fins the heat sink, the entire heat sink is electrically connected together. As such the entire heat sink can readily be electrically grounded by making a single electrical ground connection.

The foot sections of the connected, adjacent fins cooperate to form a substantially continuous attachment surface. The attachment surface of the connected fins can then be secured to another part of the solar receiver as previously described, such as the heat spreader plate or a secondary optic. In various embodiments, when the fins are attached to the heat spreader plate, the grounding tabs do not overlie and extend beyond an edge of the plate. In the case of the heat spreader plate, the broad attachment surface provides a large contact area that facilitates heat transfer from the plate to the fin. The foot sections also help to stabilize the fins and maintain the spacing between them.

Although FIG. 6A-6C illustrate a fin with a fin section and a single foot section, it should be appreciated that a fin may also have multiple foot sections. In some embodiments, the fin section has two adjacent edges that are connected to two foot sections, each of which have any or all of the characteristics described above in connection with foot section 604. A row of such fins may be connected through the foot sections to form two attachment surfaces. The attachment surfaces of the fin row can then be coupled, for example, to both a secondary optic and a heat spreader plate, as discussed earlier in connection with FIG. 5.

In another embodiment of the present invention, a method for forming the solar receiver 102 illustrated in FIG. 2 will be described. Initially, a receiver subassembly (e.g., an arrangement including a heat spreader plate, photovoltaic cell and protective cover) is formed using a lamination process. In this process, a heat spreader plate 202 is laminated together with a photovoltaic cell 104 and a protective cover 236. The arrangement of these components may be similar or identical to what was discussed above in connection with FIG. 2 (e.g., the cell 104 may be in a recess 240, the heat spreader plate 202 may have a front surface 238 that extends beyond the cell 104, etc.) After the lamination operation, front fins 204 are attached to the frontside of the heat spreader plate 202. Rear fins 206 are attached to the backside of the heat spreader plate 202. The order of attachment is not critical and the rear fins 206 may be attached prior to the front fins 204. Accordingly, the solar receiver 102 illustrated in FIG. 2 is formed. An identical or similar process, using possibly different types of fins in different orientations, can be applied to form any of the solar receivers (e.g., the solar receivers illustrated in FIGS. 2, 4A and 5) described in the present application.

Although only a few embodiments of the invention have been described in detail, it should be appreciated that the invention may be implemented in many other forms without departing from the spirit or scope of the invention. It should be appreciated that any feature discussed in connection with any figure may be incorporated into any embodiment described herein. By way of example, fins with foot sections are discussed in connection with FIGS. 6A-6C. Such fin designs may be applied to any of the fins illustrated in the preceding figures. In the foregoing description, various concepts and terms may have a meaning in some embodiments that is not explicitly recited in the specification but are supported by the drawings. By way of example, a “cell plane” can refer to a reference plane that is defined by the photovoltaic cell and/or is coplanar with the active face of the cell. The cell plane may extend between the front and rear fins of the solar receiver. To be in front of the cell plane can mean to be on the side of the cell plane where the concentrated light is coming from. To be behind the cell plane can mean to be on the opposite side of the cell plane, away from where the concentrated light is coming from after being reflected by the reflector panels. The term, “major surface” can refer to either one of two opposing surfaces on a flat, plate-like structure (e.g., a fin, a fin section, a heat spreader plate, etc.) that have the largest surface areas on the structure. Also, in the specification there may be a reference to a structure (e.g., a fin, heat spreader plate, a foot section, etc.) being perpendicular or parallel to a component. This can also be understood as meaning that the structure and/or a (major) surface of the structure defines and extends along a reference plane, and the reference plane is substantially perpendicular or parallel to the component. Therefore, the present embodiments should be considered as illustrative and not restrictive and the invention is not limited to the details given herein, but may be modified within the scope and equivalents of the appended claims.

What is claimed is:

1. A solar receiver comprising:
a photovoltaic cell;
a heat spreader plate having a frontside and an opposing backside, the photovoltaic cell being mounted on the frontside of the heat spreader plate; and
a multiplicity of heat sink fins comprising:
a first plurality of heat sink fins that are attached to and extend out of the frontside of the heat spreader plate at a location adjacent to the photovoltaic cell; and
a second plurality of heat sink fins that are attached to and extend out from the backside of the heat spreader plate.

2. A solar receiver as recited in claim 1 wherein the solar receiver includes a plurality of photovoltaic cells including said photovoltaic cell, the plurality of photovoltaic cells being arranged to form a photovoltaic cell string that extends in a longitudinal direction, at least some of the multiplicity of heat sink fins extending perpendicular to the longitudinal direction.

3. A solar receiver as recited in claim 2 wherein the first and second pluralities of heat sink fins are each arranged in a row that extends in the longitudinal direction, adjacent fins in each row being separated by gaps that define air flow channels between the fins.

4. A solar receiver as recited in claim 1 wherein:
each fin of the multiplicity of fins connects to the heat spreader plate along a connecting edge, the connecting edge extending along a width of the fin; and
the length of the connecting edge where the fin contacts the heat spreader is at least the majority of said width of the fin.

5. A solar receiver as recited in claim 1 wherein:
the first plurality of fins are arranged to fan out at different angles from the frontside of the heat spreader and are not arranged parallel to one another;
the second plurality of fins are arranged substantially parallel to one another; and
each fin of the first plurality of fins is not parallel to the second plurality of fins.

6. A solar receiver as recited in claim 1 further comprising a secondary optic that is physically supported by the first plurality of fins, the secondary optic being a longitudinally extended reflector that is positioned adjacent to the photovoltaic cell and is arranged to direct light to the photovoltaic cell using a second reflection.

7. A solar receiver as recited in claim 1 wherein each fin of the first plurality of fins is not continuous with and not connected to any fin of the second plurality of fins.

8. A solar receiver as recited in claim 1 wherein each fin of the first plurality of fins is connected to one of the fins of the second plurality of fins.

9. A solar receiver as recited in claim 1 further comprising a transparent protective cover that overlies the face of the photovoltaic cell.

10. A solar receiver as recited in claim 1 wherein:
the frontside of the heat spreader plate includes a front surface that extends above and below the photovoltaic cell, the first plurality of fins being attached to and extending outward from the front surface;
the backside of the heat spreader plate includes a back surface that is opposed to the front surface, the second plurality of fins being attached to and extending substantially perpendicular from the back surface; and
the photovoltaic cell is positioned in a recess in the front surface of the heat spreader plate.

11. A solar receiver as recited in claim 1 wherein a surface of each fin of the first plurality of fins is arranged parallel to surfaces of the second plurality of fins.

12. A solar receiver as recited in claim 1 wherein at least one of the fins of the first plurality of fins is offset from each fin of the second plurality of fins along the longitudinal direction.

13. A solar collector that is arranged to track movements of the sun in at least one dimension, the solar collector comprising:
a solar receiver as recited in claim 1 wherein the photovoltaic cell defines a cell plane that is parallel to the active face of the photovoltaic cell;
a reflector that is arranged to reflect incident light to form a flux line on the photovoltaic cell on the solar receiver wherein:
the reflector and solar receiver are arranged such that the light reflected by the reflector is not obstructed by the first plurality of heat sink fins on the frontside of the solar receiver;
the first plurality of heat sink fins are arranged in front of the cell plane towards the light reflected by the reflector; and
the second plurality of heat sink fins are arranged behind the cell plane away from the light reflected by the reflector.

14. A solar receiver comprising:
a photovoltaic cell;
a heat spreader plate, the photovoltaic cell being mounted on the heat spreader plate;
a plurality of heat sink fins that are attached to the heat spreader plate, each of the heat sink fins comprising:
a fin section;
at least one foot section, each foot section being connected to an end of the fin section and extending substantially perpendicular to the fin section, each foot section having an attachment surface that is attached to the heat spreader plate, each foot section further comprising:
a base portion; and
a grounding tab that extends out of the base portion, the grounding tab being offset relative to a surface of the base portion, the offset grounding tab and the base portion helping to define a grounding tab space underneath the foot section that is arranged to be attached to the grounding tab of another one of the multiplicity of fins.

15. A solar receiver as recited in claim 14 wherein the multiplicity of fins includes a first fin and a second fin, the fin sections of the first and second fins being arranged parallel to one another, there being gaps between the fin sections of the first and second fins, the at least one foot section including a first foot section, the first foot sections of the first and second fins being electrically attached through the welding, soldering or crimping of the grounding tab of the second fin to the first fin at the grounding tab space of the first fin.

16. A solar receiver as recited in claim 15 further comprising a longitudinally extended secondary optic that is arranged to direct light to the photovoltaic cell wherein the at least one foot section further includes a second foot section, the second foot sections of the first plurality of fins cooperating to form a surface that is attached to and physically supports the secondary optic.

17. A solar receiver as recited in claim 15 wherein each foot section further includes an interlocking tab that extends out of the base portion and a cut-out portion that is arranged to engage with the interlocking tab of another one of the fins.

18. A solar receiver as recited in claim 14 wherein the plurality of heat sink fins are electrically connected through their respective grounding tabs.

19. A method of assembling a solar receiver comprising:
forming a solar receiver subassembly by laminating a heat spreader plate, a photovoltaic cell string and a protective cover together;
after the formation of the solar receiver subassembly, attaching a plurality of rear heat sink fins to a backside of the heat spreader plate; and
attaching a plurality of front heat sink fins to a frontside of the heat spreader plate.
